(19) United States
(12) Patent Application Publication
(10) Pub. No.: US 2024/0251577 A1
(43) Pub. Date: Jul. 25, 2024

(54) DISPLAY PANEL AND DISPLAY DEVICE

(71) Applicants: Wuhan Tianma Microelectronics Co., Ltd. Shanghai Branch, Shanghai (CN); Wuhan Tianma Microelectronics Co., Ltd., Wuhan (CN)

(72) Inventors: Nana XIONG, Shanghai (CN); Chong QIAN, Shanghai (CN); Mengying JIANG, Shanghai (CN); Shengjuan LIU, Shanghai (CN); Ning KANG, Shanghai (CN)

(73) Assignees: Wuhan Tianma Microelectronics Co., Ltd. Shanghai Branch, Shanghai (CN); Wuhan Tianma Microelectronics Co., Ltd., Wuhan (CN)

(21) Appl. No.: 18/615,263

(22) Filed: Mar. 25, 2024

(30) Foreign Application Priority Data
Dec. 18, 2023 (CN) 202311747232.9

(51) Int. Cl. H10K 39/34; G06V 40/13; G09G 3/20; H10K 59/13; H10K 59/38; H10K 59/80; H10K 59/88

(52) U.S. Cl. CPC H10K 39/34; G06V 40/1318; G09G 3/20; H10K 59/13; H10K 59/38; H10K 59/8792; H10K 59/88; G09G 2300/0421; G09G 2300/08; G09G 2330/12; G09G 2354/00

(57) ABSTRACT

A display panel and a display device are provided. The display panel includes a substrate, and sensing elements and at least one light-emitting element that are located at a side of the substrate. The sensing elements include at least one first sensing element each configured to recognize fingerprint, and further comprises at least one second sensing element and/or at least one third sensing element. The at least one second sensing element each is configured to detect color temperature of ambient light. The at least one third sensing element each is configured to monitor a lifetime of one of the at least one light-emitting element.

### CROSS-REFERENCE TO RELATED APPLICATIONS

The present application claims priority to Chinese Patent Application No. 202311747232.9, filed on Dec. 18, 2023, the content of which is incorporated herein by reference in its entirety.

### TECHNICAL FIELD

The present disclosure relates to the field of display technologies, and, particularly, relates to a display panel and a display device.

### BACKGROUND

Sensing elements in the display panel are usually fixed externally to be mounted on a backside of a substrate, and light transmits multiple layers during a light transmission process to reach the sensing elements, which will produce a large loss. For the display panel using technologies of removing polarizer, a filtering layer used to replace a polarizer in the display panel includes a black matrix, and the black matrix has a strong light-shading characteristic, so that the overall transmittance of the display panel is low, and thus the sensing elements cannot receive light signals well, thereby affecting the sensitivity of the sensing elements.

### SUMMARY

In a first aspect, embodiments of the present disclosure provide a display panel. The display panel includes a substrate, at least one light-emitting element, and sensing elements. The sensing elements and the at least one light-emitting element are located at a same side of the substrate. The sensing elements include at least one first sensing element each configured to recognize fingerprint, and further includes at least one second sensing element and/or at least one third sensing element. The at least one second sensing element each is configured to detect color temperature of ambient light. The at least one third sensing element each is configured to monitor a lifetime of one of the at least one light-emitting element.

In a second aspect, embodiments of the present disclosure provide a display device including a display panel. The display panel includes a substrate, at least one light-emitting element, and sensing elements. The sensing elements and the at least one light-emitting element are located at a same side of the substrate. The sensing elements include at least one first sensing element each configured to recognize fingerprint, and further includes at least one second sensing element and/or at least one third sensing element. The at least one second sensing element each is configured to detect color temperature of ambient light. The at least one third sensing element each is configured to monitor a lifetime of one of the at least one light-emitting element.

### BRIEF DESCRIPTION OF DRAWINGS

In order to explain the embodiments of the present disclosure more clearly, the drawings used in the description of the embodiments will be briefly described below. The drawings in the following description are some embodiments of the present disclosure. Those skilled in the art can obtain other drawings based on these drawings.

FIG. 1 is a top view of a display panel provided by some embodiments of the present disclosure;

FIG. 2 is a sectional view of a display panel provided by some embodiments of the

present disclosure;

FIG. 3 is another sectional view of a display panel provided in the embodiments of the present disclosure;

FIG. 4 is another sectional view of a display panel provided by some embodiments of the present disclosure;

FIG. 5 is another sectional view of a display panel provided by some embodiments of the present disclosure;

FIG. 6 is another sectional view of a display panel provided by some embodiments of the present disclosure;

FIG. 7 is another sectional view of a display panel provided by some embodiments of the present disclosure;

FIG. 8 is another sectional view of a display panel provided in the embodiments of 5 the present disclosure;

FIG. 9 is another sectional view of a display panel provided by some embodiments of the present disclosure;

FIG. 10 is another sectional view of a display panel provided by some embodiments of the present disclosure; 10 FIG. 11 is another sectional view of a display panel provided by some embodiments

of the present disclosure;

FIG. 12 is another top view of a display panel provided by some embodiments of the present disclosure;

FIG. 13 is another sectional view of a display panel provided by some embodiments of the present disclosure;

FIG. 14 is another top view of a display panel provided by some embodiments of the present disclosure;

FIG. 15 is another top view of a display panel provided by some embodiments of the present disclosure;

FIG. 16 is another top view of a display panel provided by some embodiments of the present disclosure;

FIG. 17 is another sectional view of a display panel provided by some embodiments of the present disclosure;

FIG. 18 is another sectional view of a display panel provided by some embodiments of the present disclosure;

FIG. 19 is another sectional view of a display panel provided by some embodiments of the present disclosure;

FIG. 20 is another sectional view of a display panel provided by some embodiments of the present disclosure;

FIG. 21 is another sectional view of a display panel provided by some embodiments of the present disclosure;

FIG. 22 is another sectional view of a display panel provided by some embodiments of the present disclosure;

FIG. 23 is another top view of a display panel provided by some embodiments of the present disclosure;

FIG. 24 is another top view of a display panel provided by some embodiments of the present disclosure; and

FIG. 25 is a schematic diagram of a display device provided by some embodiments of the present disclosure.

### DESCRIPTION OF EMBODIMENTS

In order to better understand technical solutions of the present disclosure, the embodiments of the present disclosure are described in detail with reference to the drawings.

It should be clear that the described embodiments are merely some of the embodiments of the present disclosure rather than all of the embodiments. All other embodiments obtained by those skilled in the art based on the embodiments of the embodiments of the present disclosure shall fall into the scope of the present disclosure.

The terms used in the embodiments of the present disclosure are merely for the purpose of describing specific embodiment, rather than limiting the present disclosure. The terms “a”, “an”, “the” and “said” in a singular form in some embodiments of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate A alone, both A and B, and B alone. The symbol “/” in the context generally indicates that the relation between the objects in front and at the back of “/” is an “or” relationship.

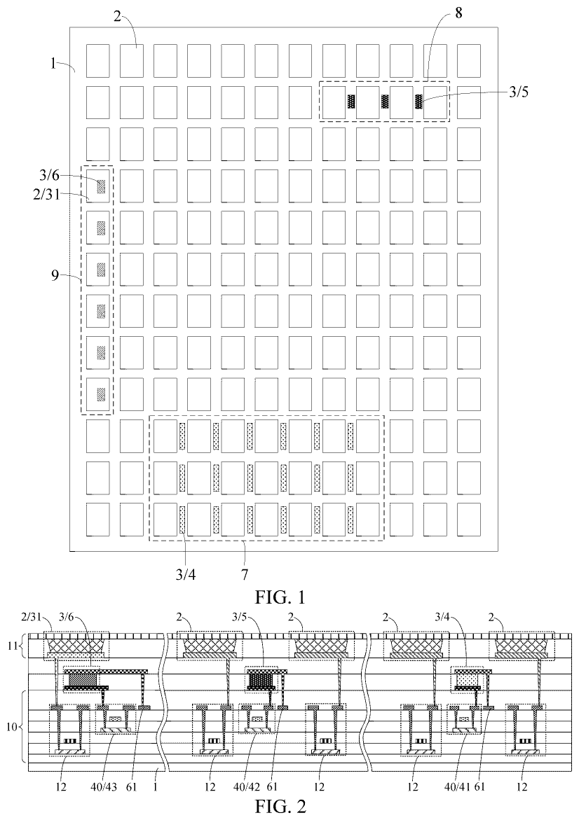

Embodiments of the present disclosure provide a display panel. FIG. 1 is a top view of a display panel provided by some embodiments of the present disclosure, and FIG. 2 is a sectional view of a display panel provided by some embodiments of the present disclosure. As shown in FIG. 1 and FIG. 2, the display panel includes a substrate 1, a light-emitting element 2 located at a side of the substrate 1, and a sensing element 3 located at a side of the substrate 1. The sensing element 3 and the light-emitting element 2 are located at a same side of the substrate 1. The sensing elements 3 include a first sensing element 4 configured to recognize fingerprint. The sensing elements 3 can include a second sensing element 5 configured to detect color temperature of ambient light, and/or a third sensing element 6 configured to monitor a lifetime of the light-emitting element 2.

The first sensing element 4 can be a light intensity sensor, light emitted by the light-emitting element 2 is transmitted to a finger and reflected by the finger, and the reflected light is incident to the first sensing element 4, and then valleys and ridges of a fingerprint are determined according to intensity of the reflected light collected by the first sensing element 4.

The second sensing element 5 can be a color temperature sensor, and the ambient light is incident to the second sensing element 5, and then the color temperature of the ambient light is detected according to the components of the ambient light with different colors collected by the second sensing element 5. When capturing an image, the color can be correctly restored according to the color temperature of the ambient light, so that the color effect of the image is more accurate and the color restoring degree is relatively high.

The third sensing element 6 can be a light intensity sensor. The light emitted by the light-emitting element 2 is directly incident to the third sensing element 6, the light-emitting brightness of the light-emitting element 2 is determined according to the intensity of the light collected by the third sensing element 6, and the lifetime attenuation of the light-emitting element 2 is then monitored according to the brightness attenuation of the light-emitting element 2.

In some embodiments of the present disclosure, a size of the first sensing element 4 can be greater than a size of the second sensing element 5 and/or a size of the third sensing element 6, so that the first sensing element 4 can receive more light reflected by the finger, thereby improving the fingerprint recognition accuracy. The size of the sensing element 3 can be understood as an area of an orthographic projection of the sensing element 3 in a direction perpendicular to a plane of the substrate 1.

In some embodiments, as shown in FIG. 1, the display panel has a fingerprint recognition region 7, and the display panel has an ambient light color temperature detection region 8 and/or a light-emitting element lifetime monitoring region 9. The first sensing element 4 is located in the fingerprint recognition region 7, the second sensing element 5 is located in the ambient light color temperature detection region 8, and the third sensing element 6 is located in the light-emitting element lifetime monitoring region 9, so that the same type of sensing elements 3 are centrally provided in a region, thereby avoiding the mutual crosstalk among different optical signals, and achieving good effect of different functions.

In the display panel provided by some embodiments of the present disclosure, the sensing element 3 and the light-emitting element 2 are located at a same side of the substrate 1, that is, the sensing element 3 is integrated in the layer of the display panel. Compared with the external fixing manner, embedding the sensing element 3 in the layer of the display panel can reduce the loss during the transmission of light to the sensing element 3, increase the amount of light that can finally be incident to the sensing element 3, improve the sensitivity of the sensing element 3, and can also be not bonded to the substrate 1, which reduces the overall thickness of the display module to a certain extent.

In the display panel provided by some embodiments of the present disclosure, at least two kind of sensing elements 3 are embedded in the display panel, and these embedded sensing element 3 can realize functions of recognizing fingerprint, and detecting the ambient light color temperature and/or monitoring the light-emitting element lifetime, so that the embedded sensing elements 3 have more diversified functions and higher integration.

When realizing the function of monitoring the lifetime of the light-emitting element, in the related art, a compensation data voltage is generally burned into a driving chip according to the pre-tested lifetime attenuation of the light-emitting element 2 before the display panel leaves factory, and then after the display panel leaves factory, the driving chip output the compensation data voltage to compensate the brightness of the light-emitting element 2. This method cannot be monitor the lifetime attenuation of the light-emitting element 2 in real time, and thus has a low compensation accuracy. However, in the embodiments of the present disclosure, the third sensing element 6 capable of monitoring the brightness of the light-emitting element 2 is integrated in the display panel, so that the lifetime attenuation of the light-emitting element 2 can be determined in real time based on the brightness attenuation of the light-emitting element 2 in the process of actual use, thereby providing more targeted compensation for the brightness of the light-emitting element 2, and improving the compensation accuracy.

In some embodiments, referring to FIG. 1 and FIG. 2, the sensing elements 3 include a second sensing element 5 and a third sensing element 6. The display panel with this structure can have three functions, i.e., embedded fingerprint recognition, ambient light color temperature detection, and light-emitting element lifetime monitoring, so that the performance of the display panel is better.

In some embodiments, as shown in FIG. 2, the display panel can include an array layer 10 and a light-emitting element layer 11 located at a side of the array layer 10 away from the substrate 1. The array layer 10 includes pixel circuits 12, at least one pixel circuit 12 is electrically connected to at least one light-emitting element 2, and the light-emitting element layer 11 includes light-emitting elements 2. The sensing element 3 is located between the array layer 10 and the light-emitting element layer 11.

In such configuration, the sensing element 3 may not affect the original manufacturing process of the light-emitting element 2, and the sensing element 3 is located above the array layer 10, and the sensing element 3 is relatively close to a light-exiting surface of the display panel. For functions of fingerprint recognition and ambient light color temperature detection, when the light reflected by the finger is transmitted to the first sensing element 4, and when the ambient light is transmitted to the third sensing element 6, the number of layers transmitted by the light reflected by the finger and the number of layers transmitted by the ambient light are relatively small, and the light loss is relatively small, which can improve the fingerprint recognition accuracy and the ambient light color temperature detection accuracy.

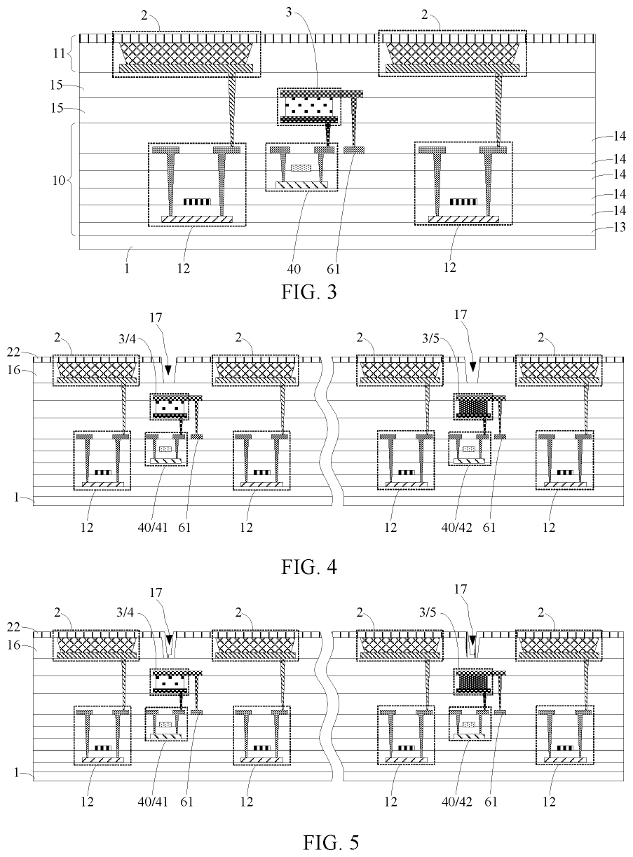

FIG. 3 is another sectional view of a display panel provided by some embodiments of the present disclosure. As shown in FIG. 3, the array layer 10 may include a buffer layer 13 and multiple first insulating layers 14. The buffer layer 13 is located between the substrate and the first insulating layer 14. The multiple first insulating layers 14 can include a gate insulation layer, an interlayer dielectric layer, a planarization layer, etc. At least two second insulating layers 15 can be provided between the array layer 10 and the light-emitting element layer 11. Two electrodes of the sensing element 3 are spaced apart from each other by at least one second insulating layer 15, and the sensing element 3 and the light-emitting element layer 11 are spaced apart from each other by at least one second insulating layer 15.

FIG. 4 is another sectional view of a display panel provided by some embodiments

of the present disclosure. In some embodiments, in combination with FIG. 2 and FIG. 4, the first sensing element 4 and/or the second sensing element 5 are located between two adjacent light-emitting elements 2 in the direction perpendicular to the plane of the substrate 1. In some embodiments of the present disclosure, when the display panel includes a first sensing element 4 and a second sensing element 5, the first sensing element 4 and the second sensing element 5 may both be located between two adjacent light-emitting elements 2.

Since all light received by the first sensing element 4 and the second sensing element 5 is incident to the interior from the outside of the display panel, the first sensing element 4 and the second sensing element 5 are located between two adjacent light-emitting elements 2, which can prevent these sensing elements 3 from being blocked by the light-emitting element 2, and ensure that these sensing elements 3 can better receive light signals.

In some embodiments, referring to FIG. 4, the light-emitting element layer 11 includes a pixel definition layer 16. The pixel definition layer 16 includes a light-transmitting hole 17. The light-transmitting hole 17 overlaps the first sensing element 4 and/or the second sensing element 5 in the direction perpendicular to the plane of the substrate 1, to increase the amount of light ultimately capable of being incident to the first sensing element 4 and/or the second sensing element 5.

When the display panel includes a first sensing element 4 and a second sensing element 5, the pixel definition layer 16 includes one light-transmitting hole 17 overlapping the first sensing element 4 and another light-transmitting hole 17 overlapping the second sensing element 5. In such configuration, as shown in FIG. 4, the cathode 22 in the light-emitting element layer 11 can be hollowed out at the light-transmitting holes 17 to increase the transmittance at the first sensing element 4 and the second sensing element 5, so that the first sensing element 4 and the second sensing element 5 receive more detection light. FIG. 5 is another sectional view of a display panel provided by some embodiments of the present disclosure. In some embodiments, as shown in FIG. 5, a cathode 22 may be concaved in the light-transmitting hole 17 to ensure the continuity of the cathode 22 throughout its face.

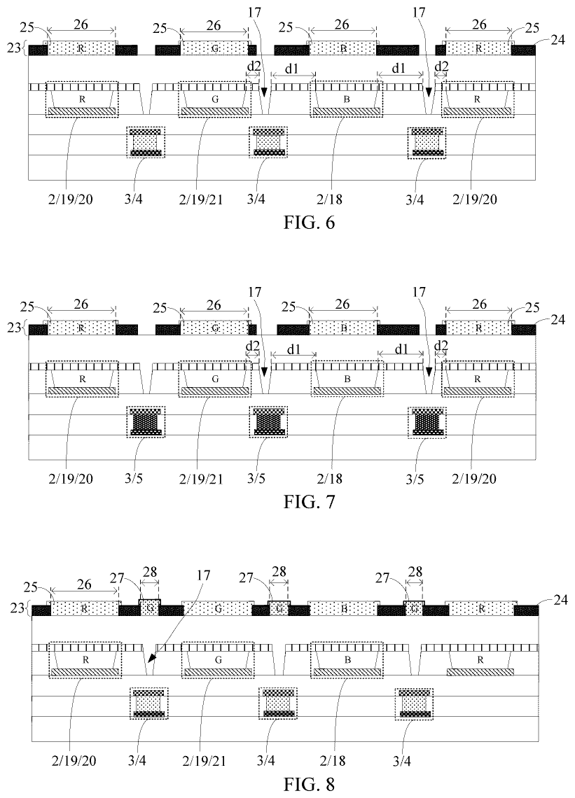

FIG. 6 is another sectional view of a display panel provided by some embodiments of the present disclosure, and FIG. 7 is another sectional view of a display panel provided by some embodiments of the present disclosure. As shown in FIG. 6 and FIG. 7, the light-emitting elements 2 include a blue light-emitting element 18 configured to emit blue light and a non-blue light-emitting element 19 configured to emit non-blue light. For a light-transmitting hole 17 located between the blue light-emitting element 18 and the non-blue light-emitting element 19, a distance d1 between the light-transmitting hole 17 and the blue light-emitting element 18 is greater than a distance d2 between the light-transmitting hole 17 and the non-blue light-emitting element 19.

In some embodiments, the non-blue light-emitting elements 19 may include a red light-emitting element 20 and a green light-emitting element 21. For a light-transmitting hole 17 located between the red light-emitting element 20 and the blue light-emitting element 18, the distance d1 between the light-transmitting hole 17 and the blue light-emitting element 18 is greater than the distance d2 between the light-transmitting hole 17 and the red light-emitting element 20. For a light-transmitting hole 17 located between a green light-emitting element 21 and a blue light-emitting element 18, the distance dl between the light-transmitting hole 17 and the blue light-emitting element 18 is greater than the distance d2 between the light-transmitting hole 17 and the green light-emitting element 21.

Compared with red light and green light, blue light has a stronger power, so when taking the blue light as interference light, it will have a greater impact on detection. In this regard, in the embodiments of the present disclosure, when designing the light-transmitting hole 17 located between the blue light-emitting element 18 and the non-blue light-emitting element 19, the distance between this light-transmitting hole 17 and the blue light-emitting element 18 can be designed to be larger, thereby reducing the risk that the blue light emitted by the blue light-emitting element 18 refracts and reflects in the layer and then emits into the first sensing element 4 or the second sensing element 5 through the light-transmitting hole 17, and reducing the influence of blue interference light on fingerprint recognition and ambient light color temperature detection.

In some embodiments, as shown in FIG. 6 and FIG. 7, when a filter layer 23 is provided at a side of the light-emitting element layer 11 away from the substrate 1, the filter layer 23 includes a black matrix 24 and a display color filter 25. The black matrix 24 includes a display aperture 26. The display color filter 25 is located in the display aperture 26. A color of light transmitting the display color filter 25 is the same as a color of light exiting from the light-emitting element 2 overlapping with the display color filter 25. A distance between the blue light-emitting element 18 and the light-transmitting hole 17 that is located between the blue light-emitting element 18 and the non-blue light-emitting element 19 can be designed larger, so that the interference of ambient light emitted by the display color filter 25 that transmits blue light (hereinafter referred to as a blue display color filter 25) can be reduced. For example, for the light-transmitting hole 17 corresponding to the first sensing element 4, the risk that the blue ambient light emitted by the blue display color filter 25 is emitted into the first sensing element 4 through the light-transmitting hole 17 can be reduced.

FIG. 8 is another sectional view of a display panel provided in the embodiments of the present disclosure. In some embodiments, as shown in FIG. 8, the display panel includes a filter layer 23 located at a side of the light-emitting element layer 11 away from the substrate 1. The filter layer 23 includes a black matrix 24 and a first color filter 27. The black matrix 24 includes a first aperture 28. The first color filter 27 is located in the first aperture 28. The first aperture 28 overlaps the first sensing element 4 in the direction perpendicular to the plane of the substrate 1, and the first color filter 27 is configured to transmit green light.

In such structure, after the light emitted by the red light-emitting element 20, green light-emitting element 21 and blue light-emitting element 18 is incident to the finger and reflected by the finger, only the reflected green light can be incident to the first sensing element 4 after passing through the first color filter 27, that is, such structure takes green light as a detection light for fingerprint recognition. On the one hand, the green light has a high brightness, and the detection accuracy will relatively high when taking the green light as the detection light. On the other hand, the first sensing element 4 detects the fingerprint by using the light emitted by the light-emitting element 2 as the detection light, since a wave band of the infrared light is close to a wave band of the red light, and a wave band of the ultraviolet light is close to a wave band of the blue light, if the first color filter 27 is designed to transmit red light or blue light, some infrared light or ultraviolet light in the ambient light emitted from outside the display panel may pass through the first color filter 27 to be incident to the first sensing element 4, and the infrared light or ultraviolet light, serving as noise, will interfere the detection, affecting the detection accuracy. The present disclosure can prevent infrared light and ultraviolet light in ambient light from being incident to the first sensing element 4 by setting the first color filter 27 to transmit green light, thus improving the fingerprint recognition accuracy.

Although the first sensing element 4 only receives green light, a distribution density of the first sensing elements 4 in the fingerprint recognition region 7 can still be designed to be consistent with a distribution density of the light-emitting element 2, that is, in addition to that the first sensing element 4 is provided at a side of the green light-emitting element 21, the first sensing element 4 can be provided between the red light-emitting element 20 and the blue light-emitting element 18. The first sensing element 4 provided between the red light-emitting element 20 and the blue light-emitting element 18 can receive the green reflected light transmitted obliquely from a long distance, which helps to improve the fingerprint recognition accuracy.

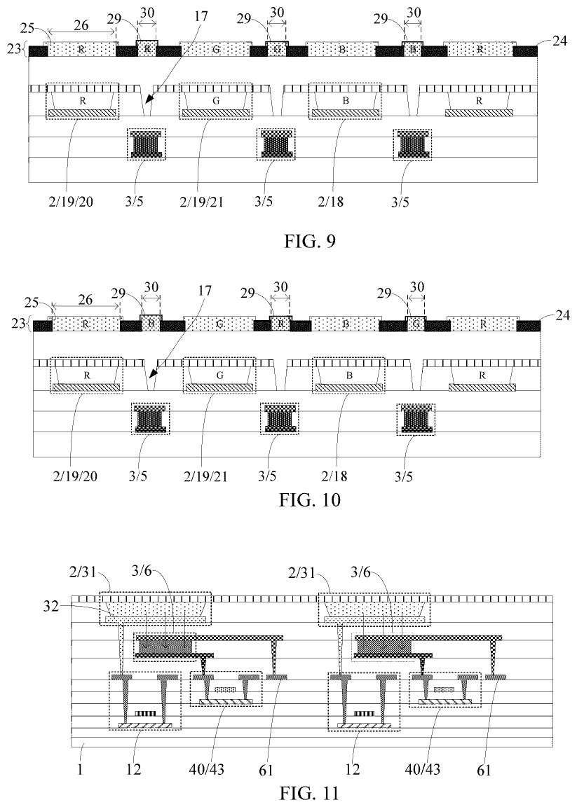

FIG. 9 is another sectional view of a display panel provided by some embodiments of the present disclosure. In some embodiments, as shown in FIG. 9, the display panel includes a filter layer 23 located at a side of the light-emitting element layer 11 away from the substrate 1. The filter layer 23 includes a black matrix 24 and second color filters 29 of at least two types. The black matrix 24 has a second aperture 30. The second color filter 29 is located in the second aperture 30. The second aperture 30 overlaps the second sensing element 5 in the direction perpendicular to the plane of the substrate 1, and at least two second color filters 29 of at least two types transmit light of different colors.

In some embodiments, the filter layer 23 includes second color filters 29 of three types configured to transmit red light, green light, and blue light respectively. The ambient light transmits the second color filters 29 of three types and then are incident into corresponding second sensing elements 5. Different second sensing elements 5 collect ambient light of different colors, and then determine red light, green light and blue light in the ambient light according to the collected ambient light of different colors, and then determine the color temperature of the ambient light.

FIG. 10 is another sectional view of a display panel provided by some embodiments of the present disclosure. In some embodiments, as shown in FIG. 10, a color of light transmitting the second color filter 29 is different from a color of light exiting from the light-emitting element 2 adjacent to the second color filter 29. With such configuration, the large-angled light emitted by the light-emitting element 2 cannot be emitted out through its adjacent second color filter 29, which can avoid the problem of crosstalk between adjacent light-emitting elements 2, thereby improving image contrast.

FIG. 11 is another sectional view of a display panel provided by some embodiments of the present disclosure. In some embodiments, as shown in FIG. 11, the light-emitting elements 2 include a first light-emitting element 31 electrically connected to a pixel circuit 12. The first light-emitting element 31 includes a light-emitting anode 32. In the direction perpendicular to the plane of the substrate 1, the third sensing element 6 overlaps the first light-emitting element 31.

By designing the anode of the first light-emitting element 31 as the light-transmitting anode 32, and designing the third sensing element 6 to overlap the first light-emitting element 31, the light emitted by the first light-emitting element 31 passes through the light-transmitting anode 32 towards the substrate 1 and then is incident to the third sensing element 6. Therefore, brightness of light emitted by the first light-emitting element 31 can be determined according to intensity of the light collected by the third sensing element 6, so as to infer the lifetime attenuation of the light-emitting element 2 in the display panel.

In such configuration, the third sensing element 6 is located directly below the first light-emitting element 31, so that the third sensing element 6 can directly receive most of the light emitted by the first light-emitting element 31, thereby improving the detection accuracy of the third sensing element 6 on the brightness of the light emitted by the first light-emitting element 31. The configuration where the third sensing element 6 overlaps the first light-emitting element 31 can save the additional space occupied by the third sensing element 6 in the horizontal direction.

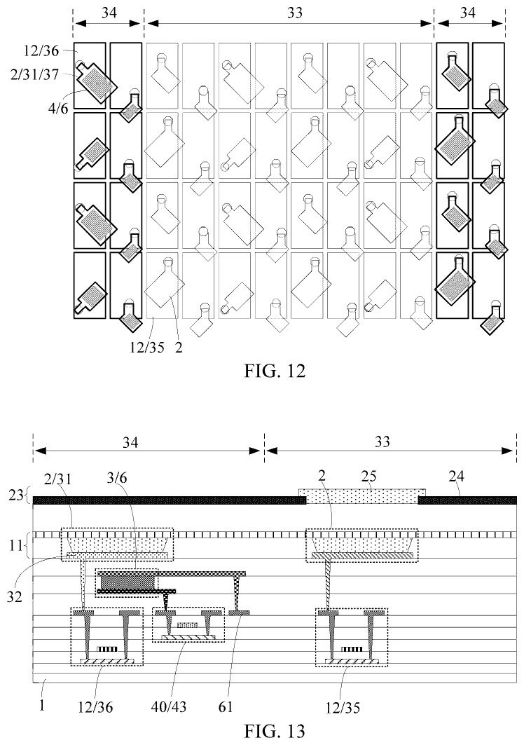

FIG. 12 is another top view of a display panel provided by some embodiments of the present disclosure, and FIG. 13 is another sectional view of a display panel provided by some embodiments of the present disclosure. In some embodiments, as shown in FIG. 12 and FIG. 13, the display panel includes a display region 33 and a dummy region 34 located at at least one side of the display region 33. The display panel can include a filter layer 23. The filter layer 23 is located at a side of the light-emitting element layer 11 away from the substrate 1. The filter layer 23 includes a black matrix 24 which covers the dummy region 34. The pixel circuit 12 includes a display pixel circuit 35 located in display region 33, and a dummy pixel circuit 36 located in the dummy region 34. The first light-emitting element 31 is located in the dummy region 34 and is electrically connected to the dummy pixel circuit 36.

In order to ensure etching uniformity, the display panel provides some dummy pixel circuits 36 and dummy light-emitting elements 37 at the periphery of the display region 33. The dummy pixel circuits 36 are not electrically connected to the dummy light-emitting elements 37, so that the dummy light-emitting elements 37 will not emit light. In some embodiments of the present disclosure, at least one dummy light-emitting elements 37 is connected to the dummy light-emitting element 36, and is set as the first light-emitting element 31.

When the display panel operates, since the first light-emitting element 31 (the dummy light-emitting element 37) is connected to the dummy pixel circuit 36, the first light-emitting element 31 (dummy light-emitting element 37) can emit light normally, but the light emitted by this first light-emitting element 31 (dummy light-emitting element 37) will not emit light from the display panel due to being blocked by the above black matrix 24. The light emitted by this first light-emitting element 31 (dummy light-emitting element 37) passes through the light-transmitting anode 32 and then is incident to the third sensing element 6, and then the brightness of the light emitted by the first light-emitting element 31 (dummy light-emitting element 37) is determined according to the intensity of the light collected by the third sensing element 6, so as to infer the lifetime attenuation of the light-emitting element 2 that is displayed normally in the display region 33.

Since the dummy light-emitting element 37 is configured to not display images, when at least one dummy light-emitting elements 37 is set as the first light-emitting element 31 in the present disclosure, the influence on the normal display brightness caused by designing the first light-emitting element 31 as the light-transmitting anode 32 can be avoided, and the third sensing element 6 in this structure will be located in the dummy region 34 accordingly, without occupying the space of the display region 33.

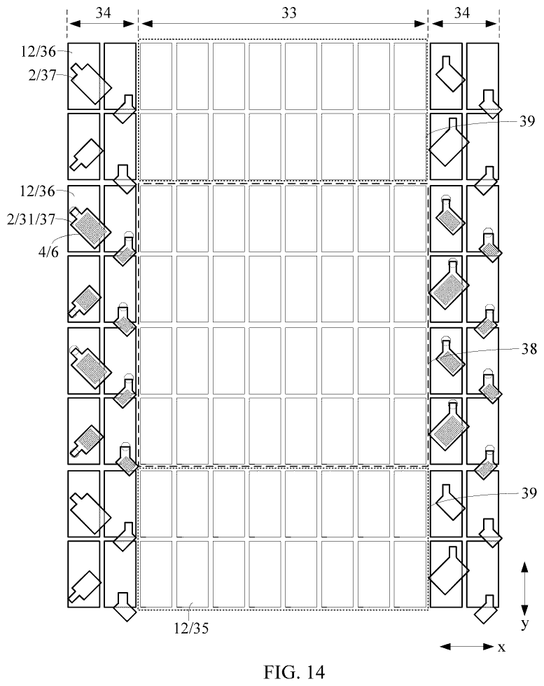

In the embodiments of the present disclosure, referring to FIG. 14, to save cost, only at least one dummy pixel circuit 36 of the dummy pixel circuits 36 may be connected to the dummy light-emitting element 37, that is, only at least one dummy light-emitting element 37 of the dummy light-emitting elements 37 is set as the first light-emitting element 31, and the third sensing element 6 is provided under the at least one dummy light-emitting element 37. The at least one first light-emitting elements 31 connected to the dummy pixel circuit 36 includes a first light-emitting element 31 configured to emit red light, a first light-emitting element 31 configured to emit green light and a first light-emitting element 31 configured to emit blue light, to monitor the lifetime of light-emitting elements 2 of different colors in the display region 33.

FIG. 14 is another top view of a display panel provided by some embodiments of the present disclosure. In some embodiments, as shown in FIG. 14, the dummy regions 34 and the display region 33 are arranged along a first direction x. The display region 33 includes a first sub-region 38 and second sub-regions 39 located at both sides of the first sub-region 38 in a second direction y, that is, the first sub-region 38 is a display region in the middle. The second direction y intersects the first direction x. At least one first light-emitting element 31 of the first light-emitting elements 31 is located at a side of the first sub-region 38 in the first direction x.

When the display panel displays an image, since the uneven display at a middle portion of the image will be more obviously visible by human eyes, when arranging the first light-emitting elements 31, at least one first light-emitting element 31 of the first light-emitting elements 31 can be arranged at a side of the middle display region 33, that is, being arranged in the middle region of the dummy region 34. In this case, the brightness attenuation of the first light-emitting element 31 will more closely reflect the brightness attenuation of the light-emitting element 2 in the middle display region 33, so that when the brightness of the light-emitting element 2 in the display region 33 is compensated according to the brightness attenuation of the first light-emitting element 31, the improvement effect of the display uniformity in the middle display region 33 will be better.

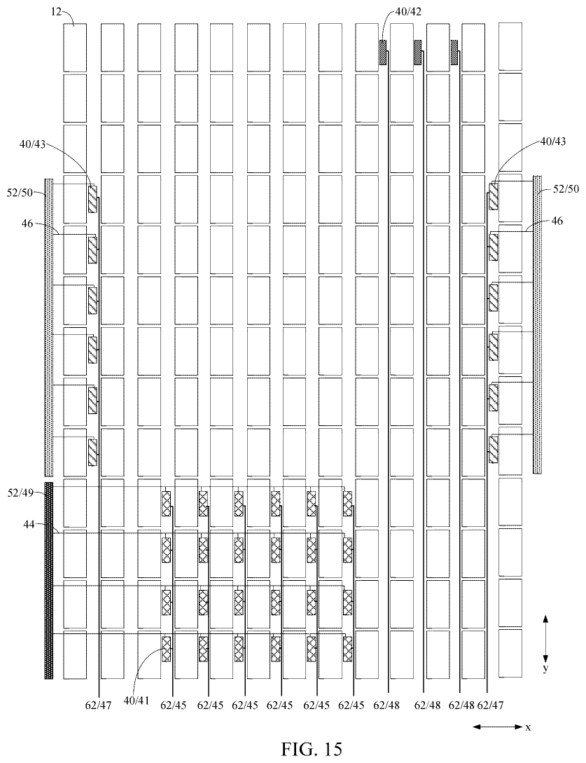

FIG. 15 is another top view of a display panel provided by some embodiments of the present disclosure. In some embodiments, in combination with FIG. 2 and FIG. 15, the display panel includes pixel circuits 12. At least one pixel circuit 12 of the pixel circuits 12 is electrically connected to the light-emitting element 2. The display panel can include driving circuits 40. The driving circuits 40 include a first driving circuit 41 electrically connected to the first sensing element 4, a second driving circuit 42 electrically connected to the second sensing element 5, and a third driving circuit 43 electrically connected to the third sensing element 6.

A number of the pixel circuits 12 arranged in the first direction x is M, a number of the first driving circuits 41 arranged in the first direction x is x1, a number of the second driving circuits 42 arranged in the first direction x is x2, and a number of the third driving circuits 43 arranged in the first direction x is x3, where x1+x2+x3<M. A number of the pixel circuits 12 arranged in the second direction y is N, a number of the first driving circuits 41 arranged in the second direction y is y1, a number of the second driving circuits 42 arranged in the second direction y is y2, and a number of the third driving circuits 43 arranged in the second direction y is y3, where y1+y2+y3<N. The second direction y intersects the first direction x.

It can be understood that, for multiple pixel circuits 12 arranged in a matrix, multiple pixel circuits 12 arranged in the first direction x are electrically connected to one scanning line (not shown in the drawings), and such horizontal scanning line can be regarded as a horizontal channel corresponding to the pixel circuit 12. Multiple pixel circuits 12 arranged in the second direction y are electrically connected to one data line (not shown in the drawings), and such longitudinal data line can be regarded as a longitudinal channel corresponding to the pixel circuit 12.

Driving of at least one of the driving circuits 40 may be similar to the driving of the pixel circuits 12. For example, referring to FIG. 15, since there are more first sensing elements 4 and third sensing elements 6, there are more first driving circuits 41 and third driving circuits 43, correspondingly. For multiple first driving circuits 41, multiple first driving circuits 41 arranged in the first direction x are electrically connected to one first control line 44, multiple first driving circuits 41 arranged in the second direction y are electrically connected to one first reading line 45, at least one of third driving circuits 43 arranged in the first direction x is electrically connected to one second control line 46, and multiple third driving circuits arranged in the second direction y are electrically connected to one third reading line 47.

Since the number of the second sensing elements 5 is relatively small, the number of corresponding second driving circuits 42 is also relatively small, so that each second driving circuit 42 can be electrically connected to one second reading line 48. If the number of the second sensing elements 5 is large, the second driving circuit 42 can adopt a similar driving manner to the first driving circuit 41 and the third driving circuit 43, that is, multiple second driving circuits 42 arranged in the first direction x are electrically connected to one third control line, and multiple second driving circuits 42 arranged in the second direction y are electrically connected to one second reading line, which will not be repeated herein.

The first control line 44 and the second control line 46 that are horizontal can be regarded as a horizontal channel corresponding to the driving circuit 40, and the first reading line 45, the second reading line 48, and third reading line 47 that are longitudinal can be regarded as a longitudinal channel corresponding to the driving circuit 40. By designing x1+x2+x3 to be smaller than or equal to M, it is avoided that the sum of horizontal channels corresponding to the driving circuit 40 is excessively large, and then it is avoided that there are too many control lines to difficultly avoid horizontal signal lines such as scanning lines, which is convenient to optimize the wiring of the control lines. By designing y1+y2+y3 to be smaller than or equal to N, it is avoided that the sum of the longitudinal channels corresponding to the driving circuit 40 is excessively large, and then it is avoided that there are too many reading lines to difficultly avoid longitudinal signal lines such as data lines, which is convenient to optimize the wiring of the reading lines.

In some embodiments, as shown in FIG. 15, the first driving circuits 41, the second driving circuits 42, and the third driving circuits 43 are staggered from each other in the first direction x, and are also staggered from one another in the second direction y.

In this case, the horizontal channel for the first driving circuit 41 and the horizontal channel for the third driving circuit 43 do not overlap, the first control line 44 and the second control line 46 can be staggered from each other. The longitudinal channel for the first driving circuit 41, the longitudinal channel for the second driving circuit 42, and the longitudinal channel for the third driving circuit 43 do not overlap one another. The first reading line 45, the second reading line 48, and the third reading line 47 can be staggered from each other.

In some embodiments, as shown in FIG. 15, when multiple first driving circuits 41 arranged in the first direction x are electrically connected to one first control line 44 and one or more third driving circuits 43 arranged in the first direction x are electrically connected to one second control line 46, the display panel includes a first sensing shift circuit 49 electrically connected to the first control line 44, and a second sensing shift circuit 50 electrically connected to the second control line 46. When the first driving circuits 41 and the third driving circuits 43 are staggered from each other in the second direction y, the first sensing shift circuits 49 and the second sensing shift circuits 50 are staggered from each other in the second direction y, so that it is conducive to the optimal design of the positions of the sensing shift circuits, thereby reducing the frame width of the sensing shift circuit occupied in the frame region.

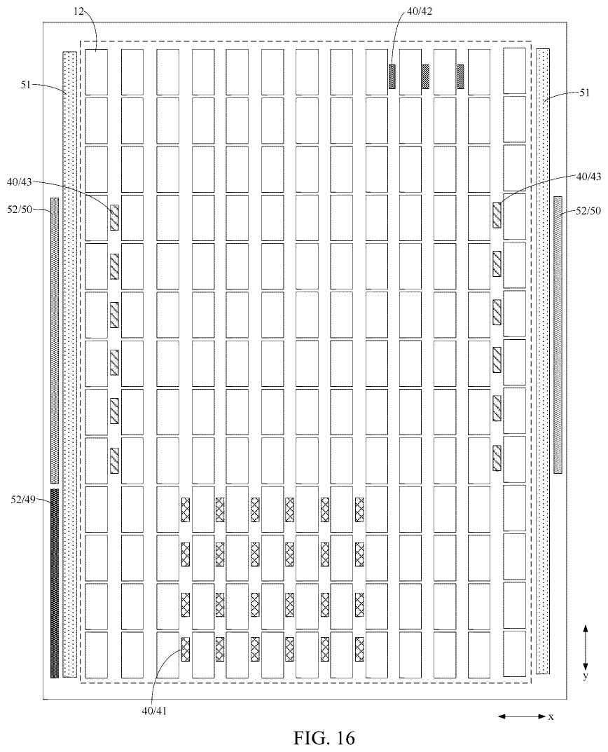

FIG. 16 is another top view of a display panel provided by some embodiments of the present disclosure. In some embodiments, in combination with FIG. 2 and FIG. 16, the display panel includes pixel circuits 12 and a display shift circuit 51. At least one of the pixel circuit 12 is electrically connected to the light-emitting element 2, and the display shift circuit 51 is electrically connected to the pixel circuit 12 (not shown in the drawings). The display shift circuit 51 may include a scanning shift circuit and a transmitting shift circuit, the scanning shift circuit is electrically connected to the pixel circuit 12 through the scanning line, and the transmitting shift circuit is electrically connected to the pixel circuit 12 through the light-emitting control signal line.

The display panel can include a driving circuit 40 and a sensing shift circuit 52. The driving circuit 40 is electrically connected to the sensing element 3 (not shown in the drawings), and the sensing shift circuit 52 is electrically connected to at least one of the driving circuits 40. As previously described, the sensing shift circuits 52 may include a first sensing shift circuit 52 electrically connected to the first driving circuit 41, and a second sensing shift circuit 52 electrically connected to the third driving circuit 43.

The display shift circuit 51 is located at a side of the sensing shift circuit 52 away from an edge of the display panel adjacent to the sensing shift circuit 52.

On the one hand, since the number of transistors in the display shift circuit 51 is larger, so that the size of the display shift circuit 51 is larger, and the load is larger. By designing the display shift circuit 51 to be closer to the pixel circuit 12, the distance between the display shift circuit 51 and the pixel circuit 12 can be shortened, so that the attenuation of the scanning signal and the light-emitting control signal during the transmission process can be reduced. On the other hand, the display shift circuit 51 is relatively far away from an outer edge of the display panel, so that the risk of static damage to the display shift circuit 51 can be reduced, thereby improving the display reliability.

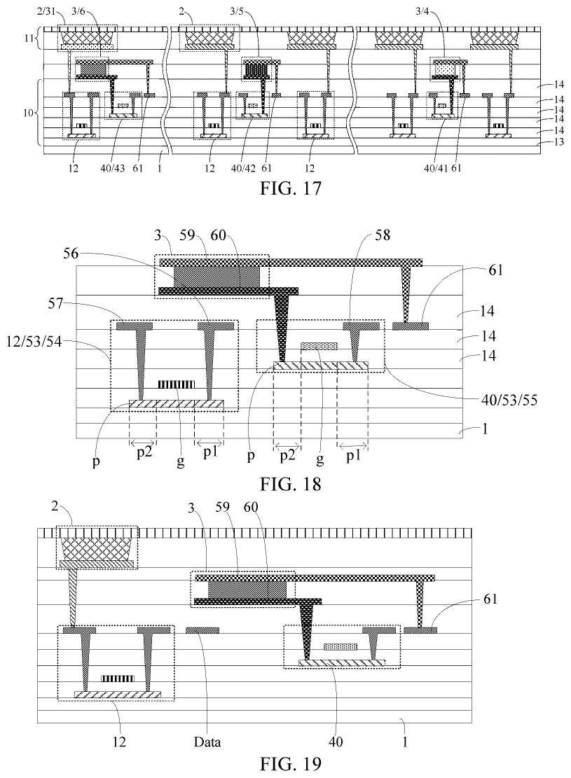

FIG. 17 is another sectional view of a display panel provided by some embodiments of the present disclosure, and FIG. 18 is another sectional view of a display panel provided by some embodiments of the present disclosure. In some embodiments, combining FIG. 17 and FIG. 18, as shown in FIG. 17, the display panel includes driving circuits 40, and the driving circuits 40 include a first driving circuit 41 electrically connected to the first sensing element 4, a second driving circuit 42 electrically connected to the second sensing element 5, and a third driving circuit 43 electrically connected to the third sensing element 6.

The first driving circuit 41, the second driving circuit 42 and the third driving circuit 43 each includes a transistor 53. The transistor 53 includes an active layer p and a gate g. The active layer p includes a first doping region p1 and a second doping region p2. For transistors 53 in the first driving circuit 41, the second driving circuit 42 and the third driving circuit 43 that of a same type, the active layers p of these transistors 53 are provided in a same layer, and the gates g of these transistors 53 are provided in a same layer, so as to reduce the total thickness of the layers occupied by these three types of driving circuits 40 as much as possible.

The first driving circuit 41, the second driving circuit 42, and the third driving circuit 43 may include transistors 53 of only one type, or include transistors 53 of two types. For example, the first driving circuit 41, the second driving circuit 42 and the third driving circuit 43 each include only N-type transistors or only P-type transistors, and in this case, the active layers p of the transistors 53 in the three types of driving circuits 40 are provided in a same layer, and the gates g of the transistors 53 in the three types of driving circuits 40 are provided in a same layer. For another example, at least one of the first driving circuit 41, the second driving circuit 42 and the third driving circuit 43 includes both an N-type transistor and a P-type transistor, and in this case, the active layers p of the P-type transistors in these three types of driving circuits 40 are provided in a same layer, the gates g of the P-type transistors in these three types of driving circuits 40 are provided in a same layer, and the active layers p of the N-type transistors in these three types of driving circuits 40 are provided in a same layer, and the gates g of the N-type transistors in these three types of driving circuits 40 are provided in a same layer.

In some embodiments, in combination with FIG. 17 and FIG. 18, the display panel includes pixel circuits 12 and driving circuits 40. At least one of the pixel circuits 12 is electrically connected to the light-emitting element 2, and the driving circuit 40 is electrically connected to the sensing element 3. The pixel circuit 12 and the driving circuit 40 each includes a transistor 53 that includes an active layer p and a gate g, and the active layer p includes a first doping region p1 and a second doping region P2. The transistor 53 in the pixel circuit 12 includes a first transistor 54. The transistor 53 in the driving circuit 40 includes a second transistor 55. The active layer p of the first transistor 54 and the active layer p of the second transistor 55 are arranged in different layers.

If the active layers p of all transistors 53 in the pixel circuits 12 and the driving circuits 40 are located in a same layer, the wiring in the semiconductor layer will be too complex. In order to avoid short circuit, it is inevitable to increase the spacing between wires, which will affect the arrangement of the pixel circuits 12 and the driving circuits 40. However, in the embodiments of the present disclosure, the active layer p of the first transistor 54 in the pixel circuit 12 is provided and the active layer p of the second transistor 55 in the driving circuit 40 are provided in different layers, so that the distance between the active layer p of the first transistor 54 and the active layer p of the second transistor 55 in the direction perpendicular to the plane of the substrate 1 can be no longer too large, and the active layer p of the first transistor 54 can even overlap the active layer p of the second transistor 55. In this case, the overall space width occupied by the pixel circuit 12 and the driving circuit 40 can be reduced.

The first transistor 54 and the second transistor 55 can be different types of transistors 53. For example, the first transistor 54 is a P-type transistor, the second transistor 55 is an N-type transistor, and the active layer p of the second transistor 55 can be located at a side of the gate g of the first transistor 54 away from the substrate 1.

In some embodiments, as shown in FIG. 18, the first doping region p1 of the active layer p in the first transistor 54 is electrically connected to a first electrode 56, and the second doping region P2 of the active layer p in the first transistor 54 is electrically connected to a second electrode 57. The first doping region p1 of the active layer p in the second transistor 55 is electrically connected to a third electrode 58. In order to reduce the overall thickness of the layers, the first electrode 56, the second electrode 57, and the third electrode 58 can be provided in a same layer.

In some embodiments, as shown in FIG. 18, the sensing element 3 includes an upper electrode 59 and a lower electrode 60. The upper electrode 59 is located at a side of the lower electrode 60 away from the substrate 1. The lower electrode 60 is electrically connected to the second doping region P2 of the active layer p in the second transistor 55. The upper electrode 59 is electrically connected to the fixed potential line 61. The fixed potential line 61 may be a ground signal line. The lower electrode 60 and the active layer p in the second transistor 55 are spaced apart from each other by at least one first insulating layer 14. The lower electrode 60 is electrically connected to the second doping region P2 of the active layer p in the second transistor 55 after penetrating through a via hole that penetrates through the first insulation layer 14.

In this structure, the lower electrode 60 is electrically connected to the second doping region P2 of the active layer p in the second transistor 55 after directly passing through the via hole that penetrates through the first insulation layer 14, without providing a fourth electrode in a same layer as the third electrode 58 corresponding to the second doping region P2 of the active layer p in the second transistor 55, which can save space.

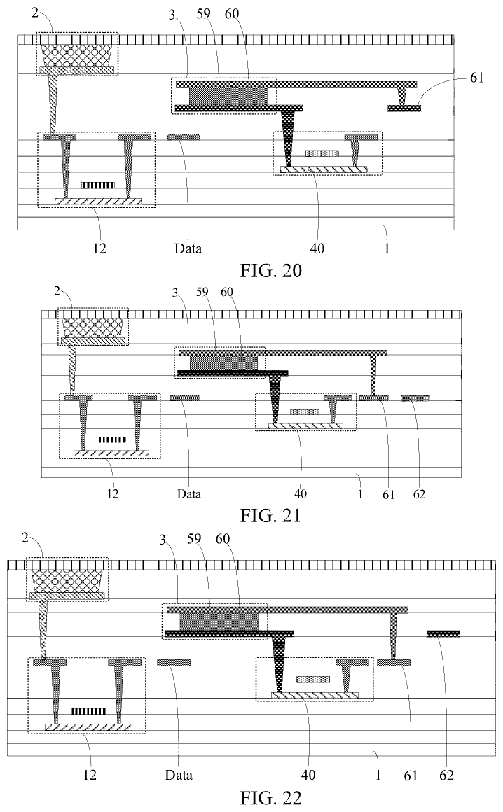

FIG. 19 is another sectional view of a display panel provided by some embodiments of the present disclosure, and FIG. 20 is another sectional view of a display panel provided by some embodiments of the present disclosure. In some embodiments, as shown in FIG. 19 and FIG. 20, the display panel includes pixel circuits 12. At least one of the pixel circuits 12 is electrically connected to the light-emitting element 2. The pixel circuit 12 is electrically connected to a data line Data. The sensing element 3 includes an upper electrode 59 and a lower electrode 60. The upper electrode 59 is located at a side of the lower electrode 60 away from the substrate 1. The upper electrode 59 is electrically connected to a fixed potential line 61. As shown in FIG. 19, the fixed potential line 61 is provided in a same layer as the data line Data, or, as shown in FIG. 20, the fixed potential line 61 is provided in a same layer as the lower electrode 60, so as to avoid that the fixed potential line 61 occupies additional layer width. When the fixed potential line 61 and the lower electrode 60 are provided in a same layer, the fixed potential line 61 is closer to the upper electrode 59, and the connection via hole has a small depth, thereby achieving a higher connection reliability.

FIG. 21 is another sectional view of a display panel provided by some embodiments of the present disclosure, and FIG. 22 is another sectional view of a display panel provided by some embodiments of the present disclosure. In some embodiments, as shown in FIG. 21 and

FIG. 22, the display panel includes pixel circuits 12. At least one of the pixel circuits 12 is electrically connected to the light-emitting element 2. The pixel circuit 12 is electrically connected to a data line Data. The display panel includes a driving circuit 40 electrically connected to both the sensing element 3 and a reading line 62.

As shown in FIG. 21, the reading line 62 is provided in a same layer as the data line Data; or, as shown in FIG. 22, the sensing element 3 includes an upper electrode 59 and a lower electrode 60. The upper electrode 59 is located at a side of the lower electrode 60 away from the substrate 1, the lower electrode 60 is electrically connected to the driving circuit 40, and the reading line 62 is provided in a same layer as the lower electrode 60, so that the reading line 62 does not occupy additional layer width.

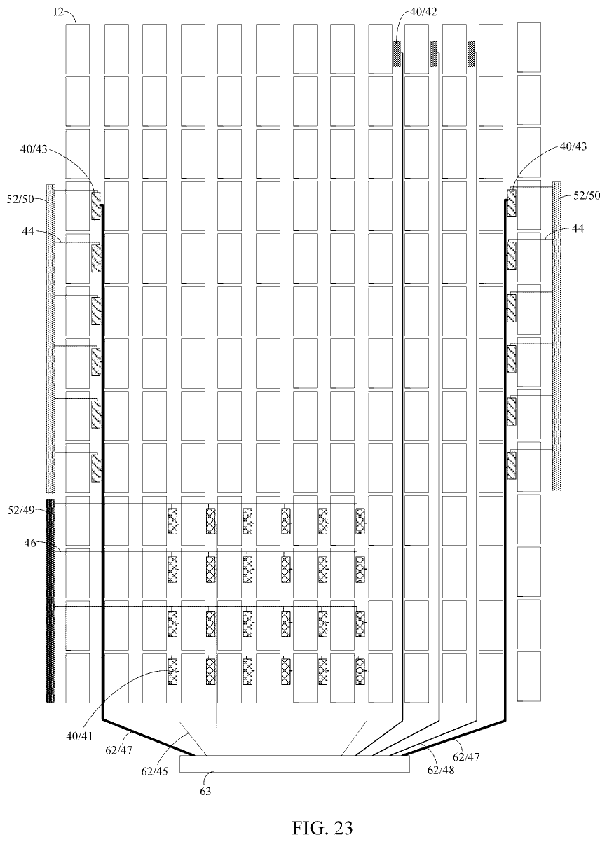

FIG. 23 is another top view of a display panel provided by some embodiments of the present disclosure. In some embodiments, the display panel includes a driving circuit 40. The driving circuits 40 include a first driving circuit 41, a second driving circuit 42 and a third driving circuit 43. The first driving circuit 41 is electrically connected to the first sensing element 4 and the first reading line 45. The second driving circuit 42 is electrically connected to the second sensing element 5 and the second reading line 48. The third driving circuit 43 is electrically connected to the third sensing element 6 and the third reading line 47.

The display panel can include a reading circuit 63. The first reading line 45, the second reading line 48 and the third reading line 47 are electrically connected to the reading circuit 63, that is, the first sensing element 4, the second sensing element 5 and the third sensing element 6 share one reading circuit 63 to read a signal, so that the display panel has a higher integration degree.

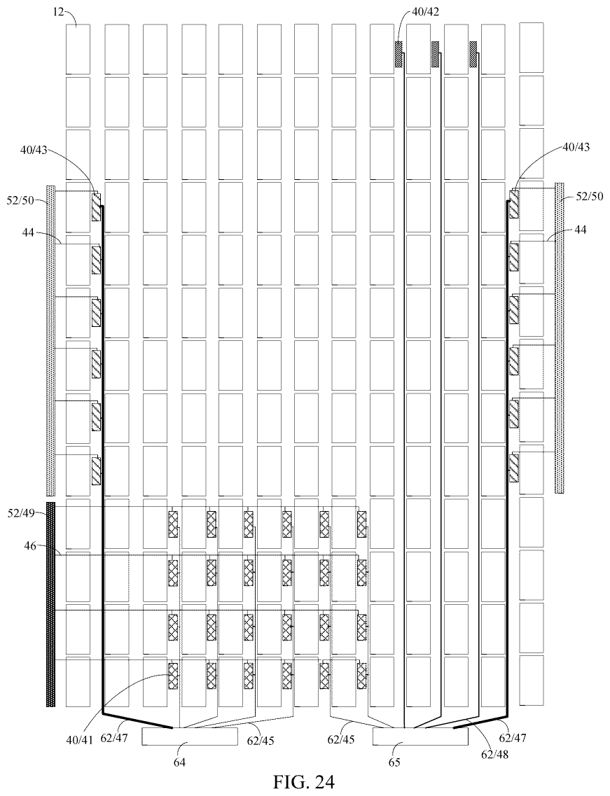

FIG. 24 is another top view of a display panel provided by some embodiments of the present disclosure. In some embodiments, as shown in FIG. 24, the display panel includes a first reading circuit 64 and a second reading circuit 65. The first reading line 45, the second reading line 48 and the third reading line 47 may be electrically connected to the first reading circuit 64 and the second reading circuit 65, respectively. For example, At least one first reading circuit 64 and at least one third reading line 47 are electrically connected to the first reading circuit 64. At least one first reading circuit 64, the second reading line 48, and at least one third reading line 47 are electrically connected to the second reading circuit 65. In this way, the demand on the number of pins of the reading circuit can be reduced, and the demand on the driving ability of the reading circuit can be reduced.

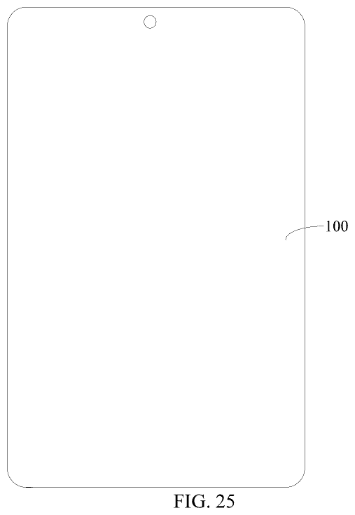

The present disclosure provides a display device. FIG. 25 is a schematic diagram of a display device provided by some embodiments of the present disclosure. As shown in FIG. 25, the display device includes the above display panel 100. The structure of the display panel 100 has been described in the above embodiments, and will not be repeated herein. The display device shown in FIG. 25 is only for illustrative purposes. The display device can be any electronic device with a display function, such as a mobile phone, a tablet computer, a laptop computer, an e-book or a television.

The above illustrates only exemplary embodiments of the present disclosure and are not intended to limit the present disclosure. Any modifications, equivalent substitutions, improvements, etc. made within the principles of the present disclosure shall fall within the scope of the present disclosure.

Finally, the above embodiments are only used to illustrate the technical solution of the present disclosure, but not to limit it. Although the present disclosure has been described in detail with reference to the foregoing embodiments, those skilled in the art should understand that modifications still can be made to the technical solutions described in the foregoing embodiments, or some or all of the technical features can be equivalently substituted. However, these modifications or substitutions do not cause the essence of the corresponding technical solutions to depart from the scope of the technical solutions of the embodiments of the present disclosure.

What is claimed is:

1. A display panel, comprising:
a substrate;
at least one light-emitting element; and
sensing elements,
wherein the sensing elements and the at least one light-emitting element are located at a same side of the substrate; the sensing elements comprise at least one first sensing element each configured to recognize fingerprint, and further comprises at least one second sensing element and/or at least one third sensing element; the at least one second sensing element each is configured to detect color temperature of ambient light; and the at least one third sensing element each is configured to monitor a lifetime of one of the at least one light-emitting element.

2. The display panel according to claim 1, wherein the sensing elements comprise the at least one second sensing element and the at least one third sensing element.

3. The display panel according to claim 1, further comprising:
an array layer; and
a light-emitting element layer located at a side of the array layer away from the substrate,
wherein the array layer comprises at least one pixel circuit, wherein one of the at least one pixel circuit is electrically connected to one of the at least one light-emitting element, and the light-emitting element layer comprises the at least one light-emitting element; and
wherein the sensing elements are located between the array layer and the light-emitting element layer.

4. The display panel according to claim 3, wherein the at least one light-emitting element comprises a plurality of light-emitting elements, and one of the at least one first sensing element and/or one of the at least one second sensing element is located between adjacent light-emitting elements of the plurality of light-emitting elements in a direction perpendicular to a plane of the substrate.

5. The display panel according to claim 4, wherein the light-emitting element layer comprises a pixel definition layer comprising at least one light-transmitting hole,
wherein one of the light-transmitting hole overlaps one of the at least one first sensing element and/or one of the at least one second sensing element in the direction perpendicular to the plane of the substrate; and
wherein the plurality of light-emitting elements comprises a blue light-emitting element configured to emit blue light and a non-blue light-emitting element configured to emit non- blue light, and, for one light-transmitting hole of the at least one light-transmitting hole located between the blue light-emitting element and the non-blue light-emitting element, a distance between the light-transmitting hole and the blue light-emitting element is greater than a distance between the light-transmitting hole and the non-blue light-emitting element.

6. The display panel according to claim 4, further comprising:
a filter layer located at a side of the light-emitting element layer away from the substrate, and comprising a black matrix and a first color filter,
wherein the black matrix comprises a first aperture, and the first color filter is located in the first aperture; and
wherein the first aperture overlaps one of the at least one first sensing element in the direction perpendicular to the plane of the substrate, and the first color filter is configured to transmit green light.

7. The display panel according to claim 4, further comprising:
a filter layer located at a side of the light-emitting element layer away from the substrate, and comprising a black matrix and at least two kinds of second color filters,
wherein the black matrix has at least two second apertures, and the at least two second color filters are located in the at least two second apertures, respectively; and
wherein one of the at least two second apertures overlaps one of the at least one second sensing element in the direction perpendicular to the plane of the substrate, and the at least two second color filters transmit light of different colors.

8. The display panel according to claim 7, wherein the color of light transmitted by one second color filter of the at least two second color filters is different from a color of light exiting from one light-emitting element of the plurality of light-emitting elements adjacent to the second color filter.

9. The display panel according to claim 3, wherein the at least one light-emitting element comprises at least one first light-emitting element electrically connected to the at least one pixel circuit, one of the at least one first light-emitting element comprises a light-transmitting anode, and one of the at least one third sensing element overlaps one of the at least one first light- emitting element in a direction perpendicular to a plane of the substrate.

10. The display panel according to claim 9, further comprising:
a filter layer located at a side of the light-emitting element layer away from the substrate and comprising a black matrix,
wherein the display panel has a display region and a dummy region located at at least one side of the display region, and the black matrix covers the dummy region; and
wherein the at least one pixel circuit comprises at least one dummy pixel circuit located in the dummy region, and the at least one first light-emitting element is located in the dummy region and is electrically connected to the at least one dummy pixel circuit.

11. The display panel according to claim 10, wherein the dummy region and the display region are arranged in a first direction, and the display region comprises a first sub-region and second sub-regions respectively located at two sides of the first sub-region in a second direction, and the second direction intersects the first direction; and
wherein one of the at least one first light-emitting element is located at a side of the first sub-region in the first direction.

12. The display panel according to claim 2, further comprising:
pixel circuits, wherein at least one of the pixel circuits is electrically connected to the at least one light-emitting element; and
driving circuits, wherein the driving circuits comprises at least one first driving circuit electrically connected to the at least one first sensing element, at least one second driving circuit electrically connected to the at least one second sensing element, and at least one third driving circuit electrically connected to the at least one third sensing element;
wherein a number of at least two of the pixel circuits arranged in a first direction is M, a number of at least one of the at least one first driving circuit arranged in the first direction is x1, a number of at least one of the at least one second driving circuit arranged in the first direction is x2, a number of at least one of the at least one third driving circuit arranged in the first direction is x3, x1+x2+x3<M; and
wherein a number of at least two of the pixel circuits arranged in a second direction is N, a number of at least one of the at least one first driving circuit arranged in the second direction is y1, a number of at least one of the at least one second driving circuit arranged in the second direction is y2, a number of at least one of the at least one third driving circuit arranged in the second direction is y3, y1+y2+y3<N, and the second direction intersects the first direction.

13. The display panel according to claim 12, wherein the at least one first driving circuit, the at least one second driving circuit, and the at least one third driving circuit are staggered from each other in the first direction and the second direction.

14. The display panel according to claim 1, further comprising:
at least one pixel circuit and at least one display shift circuit, wherein one of the at least one pixel circuit is electrically connected to one of the at least one light-emitting element, and the at least one display shift circuit is electrically connected to the at least one pixel circuit; and
driving circuits and at least one sensing shift circuit, wherein the driving circuits are electrically connected to the sensing elements, and the at least one sensing shift circuit is electrically connected to at least one of the driving circuits; and
wherein the at least one display shift circuit is located at a side of the at least one sensing shift circuit away from an edge of the display panel adjacent to the at least one sensing shift circuit.

15. The display panel according to claim 2, further comprising:
driving circuits, wherein the driving circuits comprise at least one first driving circuit electrically connected to the at least one first sensing element, at least one second driving circuit electrically connected to the at least one second sensing element, and at least one third driving circuit electrically connected to the at least one third sensing element;
wherein the at least one first driving circuit, the at least one second driving circuit, and the at least one third driving circuit each comprise at least one transistor, wherein one of the at least one transistor comprises an active layer and a gate, and the active layer comprises a first doping region and a second doping region; and
wherein the transistors of a same type in the at least one first driving circuit, the at least one second driving circuit and the at least one third driving circuit, the active layers of the transistors are arranged in a same layer, and the gates of the transistors are arranged in a same layer.

16. The display panel according to claim 1, further comprising:
pixel circuits and driving circuits,
wherein at least one of the pixel circuits is electrically connected to the at least one light-emitting element, and the driving circuits are electrically connected to the sensing elements;
wherein the pixel circuits and the driving circuits each comprise at least one transistor each comprising an active layer and a gate, wherein the active layer comprise a first doping region and a second doping region; and
wherein the at least one transistor in one of the pixel circuits comprise a first transistor, the at least one transistor in one of the driving circuits comprises a second transistor, and the active layer of the first transistor and the active layer of the second transistor are arranged in different layers.

17. The display panel according to claim 16, wherein the first doping region of the active layer of the first transistor is electrically connected to a first electrode, and the second doping region of the active layer of the first transistor is electrically connected to a second electrode; and
wherein the first doping region of the active layer of the second transistor is electrically connected to a third electrode, and the first electrode, the second electrode, and the third electrode are arranged in a same layer.

18. The display panel according to claim 16, wherein one of the sensing elements comprises an upper electrode and a lower electrode, the upper electrode is located at a side of the lower electrode away from the substrate, the lower electrode is electrically connected to the second doping region of the active layer of the second transistor, and the upper electrode is electrically connected to a fixed potential line; and
wherein the lower electrode and the active layer of the second transistor are spaced apart from each other by at least one first insulating layer, and the lower electrode is electrically connected to the second doping region of the active layer of the second transistor through a via hole that penetrates through the first insulating layer.

19. The display panel according to claim 1, further comprising:
at least one pixel circuit, wherein one of the at least one pixel circuit is electrically connected to one of the at least one light-emitting element, and the at least one pixel circuits are electrically connected to at least one data line;
wherein one of the sensing element comprises an upper electrode and a lower electrode, the upper electrode is located at a side of the lower electrode away from the substrate, and the upper electrode is electrically connected to a fixed potential line; and
wherein the fixed potential line is arranged in a same layer as the at least one data line, or is arranged in a same layer as the lower electrode.

20. The display panel according to claim 1, further comprising:
at least one pixel circuit, wherein one of the at least one pixel circuit is electrically connected to one of the at least one light-emitting element, and the at least one pixel circuit is electrically connected to at least one data line; and
at least one driving circuit electrically connected to at least one reading line and at least one of the sensing elements,
wherein the at least one reading line is provided in a same layer as the at least one data line, or
wherein one of the sensing elements comprises an upper electrode and a lower electrode, the upper electrode is located at a side of the lower electrode away from the substrate, the lower electrode is electrically connected to one of the at least one driving circuit, and the at least one reading line is provided in a same layer as the lower electrode.

21. The display panel according to claim 2, further comprising:
driving circuits, wherein the driving circuits comprise at least one first driving circuit, at least one second driving circuit, and at least one third driving circuit, the first driving circuit is electrically connected to the at least one first sensing element and a first reading line, the second driving circuit is electrically connected to the at least one second sensing element and a second reading line, and the third driving circuit is electrically connected to the at least one third sensing element and a third reading line; and
a reading circuit, wherein the first reading line, the second reading line, and the third reading line are electrically connected to the reading circuit.

22. A display device, comprising:
a display panel,
wherein the display panel comprises:
a substrate;
at least one light-emitting element; and
sensing elements,
wherein the sensing elements and the at least one light-emitting element are located at a same side of the substrate, the sensing elements comprise at least one first sensing element each configured to recognize fingerprint, and further comprises at least one second sensing element and/or at least one third sensing element, wherein the at least one second sensing element each is configured to detect color temperature of ambient light, and the at least one third sensing element each is configured to monitor a lifetime of one of the at least one light-emitting element.
